(19) United States
(12) Patent Application Publication
(10) Pub. No.: US 2024/0258242 A1
(43) Pub. Date: Aug. 1, 2024

(54) SEMICONDUCTOR PACKAGE

(71) Applicant: Samsung Electronics Co., Ltd., Suwon-si (KR)

(72) Inventors: Kitae Park, Suwon-si (KR); Chiwan Song, Suwon-si (KR); Seungmin Baek, Suwon-si (KR); Joohyung Lee, Suwon-si (KR); Joonseok Oh, Suwon-si (KR); Junghyun Cho, Suwon-si (KR)

(21) Appl. No.: 18/421,284

(22) Filed: Jan. 24, 2024

(30) Foreign Application Priority Data
Jan. 26, 2023 (KR) 10-2023-0010237

(51) Int. Cl. H01L 23/538; H01L 23/00; H01L 23/31; H01L 25/10; H01L 25/18; H10B 80/00

(52) U.S. Cl. CPC H01L 23/5386; H01L 23/3128; H01L 24/16; H01L 24/20; H01L 25/105; H01L 25/18; H10B 80/00; H01L 24/19; H01L 2224/16227; H01L 2224/19; H01L 2224/211; H01L 2224/215; H01L 2225/1035; H01L 2924/01028; H01L 2924/01029

(57) ABSTRACT

A semiconductor package includes a package body, a fan-in-chip structure (FICS) in the package body, a first redistribution structure, and a second redistribution structure. The FICS includes a first chip having a front surface and a rear surface, a bridge wiring structure including a bridge wiring layer on the rear surface of the first chip, and a bridge pad electrically connected to the bridge wiring layer. The first redistribution structure is on a bottom surface of the package body and the front surface of the first chip and includes a first redistribution element. The second redistribution structure is on a top surface of the package body and the rear surface of the first chip and includes a second redistribution element electrically connected to the bridge wiring structure.

### CROSS-REFERENCE TO RELATED APPLICATION

This application is based on and claims priority under 35 U.S.C. § 119 to Korean Patent Application No. 10-2023-0010237, filed on Jan. 26, 2023, in the Korean Intellectual Property Office, the disclosure of which is incorporated by reference herein in its entirety.

### BACKGROUND

The inventive concept relates to a semiconductor package, and more particularly, to a semiconductor package including integrated chips at high density.

One of the hot topics in the semiconductor industry is to manufacture miniaturized, multifunctional, high-performance, high-capacity, and highly reliable semiconductor products at low cost. One of the important technologies to achieve such a complex goal is semiconductor package technology. Semiconductor packaging technology requires high-density integration of chips included in a semiconductor package.

### SUMMARY

The inventive concept relates to a semiconductor package including integrated chips at high density.

According to an aspect of the inventive concept, there is provided a semiconductor package including a package body, a fan-in-chip structure (FICS) in the package body, wherein the FICS includes a first chip having a front surface and a rear surface, a bridge wiring structure including a bridge wiring layer on the rear surface of the first chip, and a bridge pad electrically connected to the bridge wiring layer, a first redistribution structure on a bottom surface of the package body and the front surface of the first chip and including a first redistribution element, and a second redistribution structure on a top surface of the package body and the rear surface of the first chip and including a second redistribution element electrically connected to the bridge wiring structure.

According to another aspect of the inventive concept, there is provided a semiconductor package including a package body having a fan-in region and a fan-out region surrounding the fan-in region, wherein the package body comprises a wiring board having a through hole in an internal region of the wiring board or a semiconductor substrate having a through hole in an internal region of the semiconductor substrate, and a body wiring structure is formed in the package body of the fan-out region, a fan-in-chip structure (FICS) in the fan-in region, wherein the FICS includes a bridge wiring structure including a first chip having a front surface that is an active surface and a rear surface that is an inactive surface, a bridge wiring layer on the rear surface of the first chip, and a bridge pad electrically connected to the bridge wiring layer, a first redistribution structure on a bottom surface of the package body and the front surface of the first chip and including a first redistribution element extending from the fan-in region to the fan-out region, and a second redistribution structure on a top surface of the package body and the rear surface of the first chip and including a second redistribution element extending from the fan-in region to the fan-out region and electrically connected to the bridge wiring structure.

According to another aspect of the inventive concept, there is provided a semiconductor package including a lower package and an upper package stacked on the lower package.

The lower package includes a package body having a body wiring structure, a fan-in region, and a fan-out region surrounding the fan-in region, wherein the body wiring structure is formed in the package body of the fan-out region, a fan-in-chip structure (FICS) in the fan-in region, wherein the FICS includes including a first chip having a front surface that is an active surface and a rear surface that is an inactive surface, and a bridge wiring structure including a bridge wiring layer on the rear surface of the first chip and a bridge pad electrically connected to the bridge wiring layer, a first redistribution structure on a bottom surface of the package body and the front surface of the first chip and including a first redistribution element extending to the fan-out region, and a second redistribution structure on a top surface of the package body and the a top surface of the bridge wiring structure and including a second redistribution element extending to the fan-out region and electrically connected to the bridge wiring structure.

The upper package includes a second chip mounted on a first side of the second redistribution structure and electrically connected to the second redistribution structure, and a third chip mounted on a second side of the second redistribution structure and electrically connected to the second redistribution structure.

### BRIEF DESCRIPTION OF THE DRAWINGS

Embodiments will be more clearly understood from the following detailed description taken in conjunction with the accompanying drawings in which:

FIG. 1 is a cross-sectional view illustrating a main part of a semiconductor package according to an embodiment;

FIG. 2 is a view illustrating a fan-in-chip structure (FICS) of FIG. 1;

FIG. 3 is an enlarged view illustrating a partial region of FIG. 1;

FIGS. 4 and 5 are plan views illustrating bridge wiring structures each positioned on the FICS of FIG. 1;

FIGS. 6 and 7 are plan views illustrating second redistribution elements and a plurality of second redistribution pads for chip connection, which are positioned on the FICS of FIG. 1;

FIG. 8 is a cross-sectional view illustrating a main part of a semiconductor package according to an embodiment;

FIG. 9 is a cross-sectional view illustrating a main part of a semiconductor package according to an embodiment;

FIGS. 10 to 17 are cross-sectional views illustrating a method of manufacturing the semiconductor package of FIGS. 1 to 3 according to an embodiment;

FIGS. 18 to 21 are cross-sectional views illustrating a method of manufacturing the semiconductor package of FIG. 9 according to an embodiment;

FIG. 22 is a cross-sectional view illustrating a main part of a semiconductor package according to an embodiment;

FIG. 23 is a cross-sectional view illustrating a main part of a semiconductor package according to an embodiment;

FIG. 24 is a block diagram illustrating a configuration of a semiconductor package according to an embodiment; and

FIG. 25 is a block diagram schematically illustrating a configuration of a semiconductor package according to an embodiment.

### DETAILED DESCRIPTION OF THE EMBODIMENTS

Hereinafter, embodiments of the inventive concept will be described in detail with reference to the accompanying drawings. Like numeral references refer to like elements, and their repetitive descriptions may be omitted.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). Unless otherwise indicated, ordinal numbers within the specification do not indicate any particular order.

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited. Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein, “formed from the same body” refers to a structure to be continuously integrated, without a discontinuous boundary surface (for example, a grain boundary), in which two components formed by a different process are not simply in contact (discontinuity), but are formed of the same material by the same process.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Additionally, when an element is referred to as being “electrically connected” an electric current is able to pass to or from element by way of the connection. Similarly, when an element electrically connects two or more elements an electrical current is able to pass between the two or more elements by traversing the element electrically connecting the two or more elements.

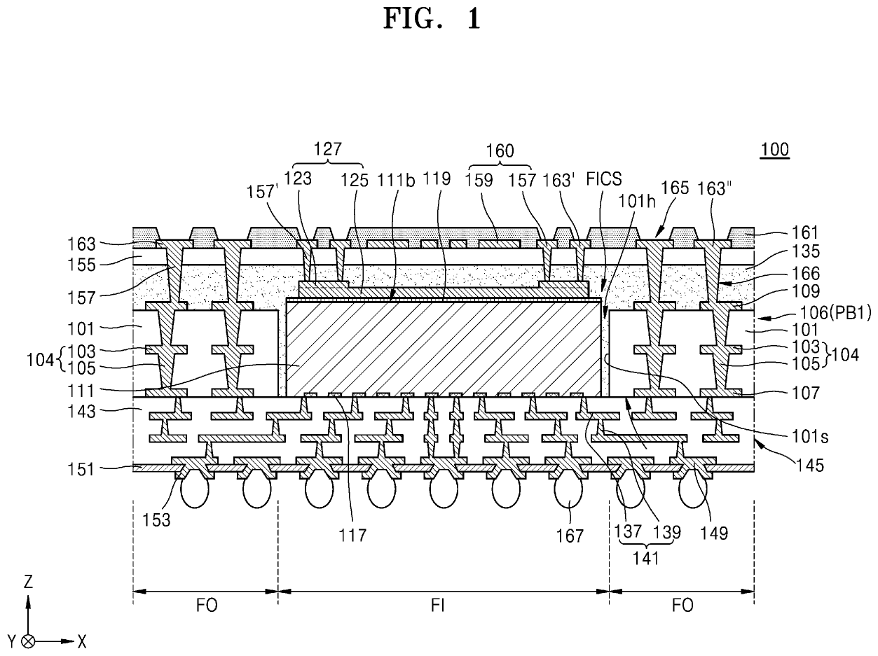

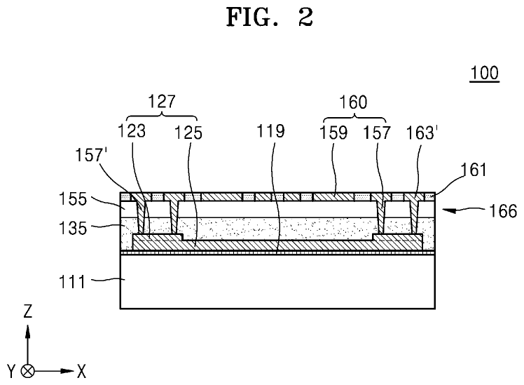

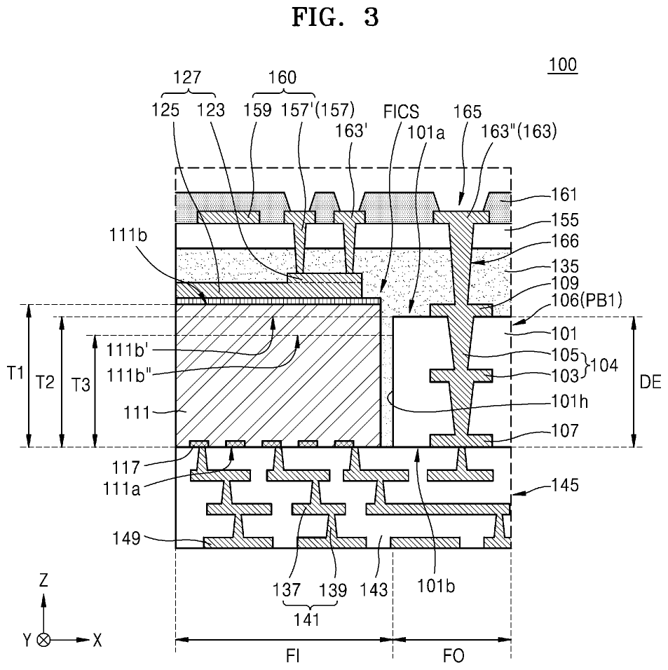

In the following description various items described herein, such as pads, may be described in the plural although the figures may only identify a single it by reference number. For example, FIG. 3 shows a plurality of first redistribution pads 149 on a bottom surface of a body 101 although only one is labeled. Similarly, FIG. 1 shows a plurality of second redistribution pads 163 on a top surface of the body 101 although only one is labeled. FIG. 1 is a cross-sectional view illustrating a main part of a semiconductor package 100 according to an embodiment, FIG. 2 is a view illustrating a fan-in-chip structure of FIG. 1, and FIG. 3 is an enlarged view illustrating a partial region of FIG. 1.

Specifically, in FIGS. 1 to 3, a first horizontal direction (such as the X direction shown in the figures, hereafter “the X direction”) may be horizontal on a first redistribution structure 145, and a second horizontal direction (such as the Y direction shown in the figures, hereafter “the Y direction”) may be perpendicular to the first horizontal direction (the X direction) on the first redistribution structure 145. A vertical direction (such as the Z direction of the figures, hereafter “the Z direction”) may be perpendicular to the first horizontal direction (the X direction) and the second horizontal direction (the Y direction).

The semiconductor package 100 may include a fan-out semiconductor package. The semiconductor package 100 may include a package body PB1. The package body PB1 may include a wiring board 106 including a fan-in region FI corresponding to a through hole 101h defined by a side wall 101s, and a fan-out region FO positioned outside of the fan-in region FI (e.g., on both sides of the fan-in region FI in the cross-section view of FIG. 1). The fan-out region FO may surround the fan-in region FI in a plan view. The fan-in region FI may correspond to a first horizontal region (e.g., a first area of a plane defined by the first and second horizontal directions) corresponding to a cross-section of the through hole that may be projected vertically (e.g., in the vertical direction) within the semiconductor package 100 and the fan-out FO region may correspond to a second horizontal area (e.g., a second area in the plane defined by the first and second horizontal directions) external to the first horizontal region that may be projected vertically (e.g., in the vertical direction) within the semiconductor package 100.

The wiring board 106 may be a part of the package body PB1. The package body PB1 may include a package element. The wiring board 106 may include an insulation board. The wiring board 106 may include a printed circuit board (PCB). The wiring board 106 may be referred to as a frame board. The semiconductor package 100 may include a fan out panel level package (FOPLP). The wiring board 106 may include a body 101 having the side wall 101s defining the through hole 101h, a body wiring structure 104 formed in the body 101, and first and second body wiring pads 107 and 109.

As illustrated in FIG. 3, the through hole 101h may pass through a top surface 101a and a bottom surface 101b of the body 101. The body 101 may be formed of and/or include at least one material selected from phenol resin, epoxy resin, and polyimide. For example, the body 101 may be formed of and/or include at least one material selected from flame retardant 4 (FR4), tetrafunctional epoxy, polyphenylene ether, epoxy/polyphenylene oxide, bismaleimide triazine (BT), thermount, cyanate ester, polyimide, and liquid crystal polymer.

The body wiring structure 104 may include a body wiring layer 103 formed in the body 101 and body vias 105 providing an electrical connection to the body wiring layer 103. The first body wiring pads 107 are positioned on the bottom surface 101b of the body 101 and are electrically connected to the body wiring structure 104 and the second body wiring pads 109 are positioned on the top surface 101a of the body 101 and are electrically connected to the body wiring structure 104.

The first body wiring pads 107 may be a part of the body wiring structure 104 positioned at the bottom surface 101b of the body 101. The second body wiring pads 109 may be a part of the body wiring structure 104 positioned at the top surface 101a of the body 101.

Each of the body wiring layer 103, the body vias 105, and the first and second body wiring pads 107 and 109 may include a metal layer. For example, the body wiring layer 103 and the first and second body wiring pads 107 and 109 may be formed of and/or include electrolytically deposited (ED) copper (Cu) foil, rolled-annealed (RA) Cu foil, stainless steel foil, aluminum (Al) foil, ultra-thin Cu foil, sputtered Cu, or a Cu alloy. The body vias 105 may be formed of and/or include, for example, Cu, nickel (Ni), stainless steel, or beryllium (Be) Cu.

The semiconductor package 100 may include a fan-in-chip structure (FICS) arranged in the through hole 101h. The FICS may be referred to as a fan-in-chip package structure. In some embodiments, the through hole 101h in the wiring board 106 corresponding to the FICS may correspond to the fan-in region FI. A body of the wiring board 106 excluding the through hole 101h may correspond to the fan-out region FO.

In some embodiments, a rear surface 111b of a first chip 111 constituting the FICS may be at a higher level than the top surface 101a of the wiring board 106 (e.g., the distance from the bottom surface 101b to the rear surface 111b may be greater than the distance from the bottom surface 101b to the top surface 101a). For example, as illustrated in FIG. 3, the first chip 111 may have a first thickness T1. The through hole 101h may have a depth DE that corresponds to the thickness of the wiring board 106. The first thickness T1 may be greater than the depth DE, so that the rear surface 111b of the first chip 111 may be at a higher level than the top surface 101a of the wiring board 106.

In some embodiments, a rear surface 111b′ of the first chip 111 constituting the FICS may be at the same level as the top surface 101a of the wiring board 106 (e.g., the distance from the bottom surface 101b to the rear surface 111b may be the same as the distance from the bottom surface 101b to the top surface 101a). For example, as illustrated in FIG. 3, the first chip 111 may have a second thickness T2, that is the same as the depth DE of the through hole, so that the rear surface 111b′ of the first chip 111 may be at the same level as the top surface of the wiring board 106. In some examples, the thickness of the first chip 111 can be reduced though a back grinding process applied to the rear surface 111b of the first chip 111.

In some embodiments, the first chip 111 or the FICS may be embedded in the through hole 101h (e.g., to be coplanar with or above a lower extent of the through hole 101h, and below an upper extent of the through hole 101h). For example, as illustrated in FIG. 3, the first chip 111 may have a third thickness T3 that may be less than the depth DE, so that a rear surface 111b″ of the first chip 111 may be at a lower level than the top surface 101a of the wiring board 106 (e.g., the distance from the bottom surface 101b to the rear surface 111b may be less than the distance from the bottom surface 101b to the top surface 101a).

In some embodiments, the first chip 111 may have a thickness in a range of about 10 micrometers to about 800 micrometers. The depth DE of the through hole 101h may be in a range of about 100 micrometers to about 1,500 micrometers.

The FICS may include the first chip 111 and a bridge wiring structure 127. The bridge wiring structure 127 may be referred to as a bridge redistribution structure. In the embodiment of FIGS. 1-3, the FICS is illustrated as including one first chip. However, the inventive concept may also be applied to other arrangements such as a stacked chip in which a plurality of chips are stacked. The first chip 111 may serve as an active device.

In some embodiments, the first chip 111 may include at least one individual device. The individual device may include one of various microelectronics devices, for example, a metal-oxide-semiconductor field effect transistor (MOSFET) such as a complementary metal-insulator-semiconductor (CMOS) transistor, an image sensor such as a system large scale integration (LSI), or a CMOS imaging sensor (CIS), a micro-electro-mechanical system (MEMS), an active device, or a passive device. The first chip 111 may be described as a bridge chip, which functions as a bridge to support the bridge wiring structure 127, such that the bridge wiring structure 127 is electrically insulated from circuitry within the first chip 111, and may also function as one of the chips described above.

In some configurations, the first chip 111 may include a logic chip, a power management integrated circuit (PMIC) chip, or a memory chip. In some embodiments, the logic chip may include a memory controller chip, a central processing unit (CPU) chip, a graphics processing unit (GPU) chip, or an application processor (AP) chip.

In some embodiments, the memory chip may include a dynamic random access memory (DRAM) chip, a static random access memory (SRAM) chip, a flash memory chip, an electrically erasable and programmable read-only memory (EEPROM) chip, a phase-change RAM (PRAM) chip, a magnetic RAM (MRAM) chip, or a resistive RAM (RRAM) chip.

The first chip 111 may have a front surface 111a and the rear surface 111b. The front surface 111a may include an active surface on which individual devices are formed, and the rear surface 111b may include an inactive surface on which individual devices are not formed. In the first chip 111, the front surface 111a, which is the active surface on which the individual devices are formed, may be positioned below the rear surface 111b which is the inactive surface. The active surface and the inactive surface may both be within the fan-in region FI.

First chip pads 117 may be arranged on the front surface 111a of the first chip 111. Each of the first chip pads 117 may include a metal pad such as an Al pad or a Cu pad. Each of the first chip pads 117 may include an electrically conductive pad.

The bridge wiring structure 127 may be arranged on or at the rear surface 11b of the first chip 111. In some embodiments, the bridge wiring structure 127 may be arranged on an insulating layer 119 arranged on or at the rear surface 11b of the first chip 111. The bridge wiring structure 127 may serve as an interposer.

The bridge wiring structure 127 may include a bridge wiring layer 125 arranged on or at the rear surface 111b of the first chip 111 and a bridge pads 123 electrically connected to the bridge wiring layer 125. In the case of a package-on-package arrangement, the bridge wiring structure 127 may include a bridge wiring line connecting additional chips, for example, second and third chips stacked on the package body PB1, as described later.

The bridge wiring layer 125 and the bridge pads 123 may be formed of the same body. Each of the bridge wiring layer 125 and the bridge pads 123 may be formed of and/or include a conductive material. Each of the bridge wiring layer 125 and the bridge pads 123 may also include or be formed of an impurity-doped semiconductor layer, for example, a silicon layer. The bridge wiring structure 127 may be arranged in the fan-in region FI and excluded from the fan-out region FO.

The semiconductor package 100 may include the first redistribution structure 145. The first redistribution structure 145 may be arranged on or at a bottom surface of the wiring board 106 and a bottom surface of the FICS. The first redistribution structure 145 may include first redistribution elements 141 extending from the fan-in region FI to the fan-out region FO in a first redistribution insulating layer 143. Each of the first redistribution elements 141 may include a first redistribution layer 137 and first redistribution vias 139 electrically connected to the first redistribution layer 137 and extending vertically to electrically connect to other components such as a chip pad.

The first redistribution elements 141 may be electrically connected to the first chip pads 117 in the fan-in region FI. For example, the first redistribution elements 141 may contact the first chip pads 117 to create an electrical connection. The first redistribution elements 141 may be formed of and/or include the same material as a body wiring structure 104.

The first redistribution structure 145 may include first redistribution pads 149 electrically connected to the first redistribution elements 141. The first redistribution pads 149 may be formed of the same body as the first redistribution elements 141, or the first redistribution pads 149 may be separate from the first redistribution elements 141 and the electrical connection may be created through contact between the first redistribution pads 149 and the first redistribution elements 141. The first redistribution pads 149 may be positioned on or at a bottom surface of the first redistribution structure 145 and on or at a top surface of the first redistribution structure 145. The first redistribution pads 149 positioned on or at a top surface of the first redistribution insulating layer 143 (e.g., the top surface of the first redistribution structure) may be a part of the first redistribution layer 137.

The first redistribution pads 149 may be formed of and/or include the same material as the first and second body wiring pads 107 and 109. A barrier metal layer 153, for example Ni layers or Cu layers, may be formed on the first redistribution pads 149. Portions of the barrier metal layer 153 may be electrically separated from one another by a first protective layer 151.

A bottom surface of the first protective layer 151 and a bottom surface of the barrier metal layer 153 may form a common bottom surface of the first redistribution structure 145. The first redistribution pads 149 may be electrically separated from one another or other components by the first protective layer 151. First external connection terminals 167, for example, solder balls, may be formed on the barrier metal layer 153.

The semiconductor package 100 may include an encapsulation layer 135. The encapsulation layer 135 may be formed on the FICS, which may be embedded in the through hole 101h, and the wiring board 106. The encapsulation layer 135 may be formed on side surfaces of the FICS in the through hole 101h, on a top surface of the FICS, and/or on the side wall 101s of the body 101.

The encapsulation layer 135 may surround the FICS in the through hole 101h in a plan view. The encapsulation layer 135 may seal the FICS in the through hole 101h. The encapsulation layer 135 may be formed of and/or include, for example, an epoxy molding compound (EMC). In some embodiments, the encapsulation layer 135 may be formed on a top surface of the body 101 and extend horizontally above the wiring board 106 to cover at least a portion of the fan-out region FO.

The semiconductor package 100 may include a second redistribution structure 166. The second redistribution structure 166 may be arranged on the top surface 101a of the wiring board 106 and the top surface of the FICS. The second redistribution structure 166 may be arranged on the top surface of the package body PB1, the rear surface 111b of the first chip 111, and/or a top surface of the bridge wiring structure 127. The second redistribution structure 166 may include second redistribution elements 160 formed in the encapsulation layer 135 and insulated by a second redistribution insulating layer 155.

The second redistribution structure 166 may include the second redistribution elements 160 which may extend horizontally to the fan-out region FO. The second redistribution elements 160 may include a second redistribution layer 159 and second redistribution vias 157. The second redistribution elements 160 may be electrically connected to the bridge wiring structure 127 of the FICS. For example, second redistribution elements 160 may be electrically connected to the bridge pads 123 and the bridge wiring layer 125. The second redistribution vias 157 may include bridge pad second redistribution vias 157′, which are electrically connected to the bridge pads 123. The second redistribution layer 159 may extend from the fan-in region FI to the fan-out region FO in a plan view. The second redistribution layer 159 may extend from the fan-in region FI to the fan-out region FO to redistribute electrical connections from the fan-in region FI. The second redistribution elements 160 may be electrically connected to the bridge pads 123 in the fan-in region FI. Because FIG. 1 is a cross-sectional view, the second redistribution layer 159 is illustrated as being apart (e.g., having gaps) but in other views and cross sections the second redistribution layer 159 may appear without a gap. The second redistribution layer 159 may include multiple electrical paths that are insulated from one another. For example, a first electrical path including a single bridge pad second redistribution via 157′ may be electrically insulated from a second electrical path that includes a different second redistribution via 157. The second redistribution elements 160 may be formed of and/or include the same material as the body wiring structure 104.

The second redistribution structure 166 may include second redistribution pads 163 electrically connected to the second redistribution elements 160. The second redistribution pads 163 may include chip connection second redistribution pads 163′, which are electrically connected to the second redistribution elements 160 arranged on a top surface of the bridge wiring structure 127. The chip connection second redistribution pads 163′ may be electrically connected to the bridge pad second redistribution vias 157′. The second redistribution pads 163 may include body connection second redistribution pads 163″, which are electrically connected to the second body wiring pads 109 arranged on the top surface of the package body PB1.

For example, the second redistribution structure 166 may include a first group of second redistribution pads 163 consisting of the chip connection second redistribution pads 163′ which are each electrically connected to a respective bridge pad second redistribution via 157′ which are each electrically connected to a respective bridge pad 123. The second redistribution structure 166 may include a second group of second redistribution pads 163 consisting of the body connection second redistribution pads 163″ which are each electrically connected to a respective second redistribution via 157 which are each electrically connected to a respective second body wiring pad 109.

The second redistribution pads 163 may be a part of the second redistribution layer 159, or the second redistribution pads 163 may be electrically connected to the second redistribution layer 159, such as by contact with the second redistribution layer 159. Each second redistribution pad 163 of the second redistribution pads 163 may be electrically separated from another second redistribution pad 163 or other components by a second protective layer 161. The second redistribution pads 163 may be formed of and/or include the same material as the first and second body wiring pads 107 and 109. The second redistribution pads 163 may be exposed externally (e.g., to the outside of the semiconductor package 100) by pad exposure holes 165. Second and third external connection terminals (not shown), for example, solder balls, may be formed on the second redistribution pads 163.

As described above, the semiconductor package 100 according to the inventive concept includes the bridge wiring structure 127 having the bridge wiring layer 125 and the bridge pads 123 on or at the rear surface 111b of the first chip 111 positioned in the package body PB1. Accordingly, the semiconductor package 100 according to the inventive concept may efficiently and densely integrate the additional chips, that is, the second and third chips stacked on the package body PB1 which may use the bridge wiring structure 127 as an interposer.

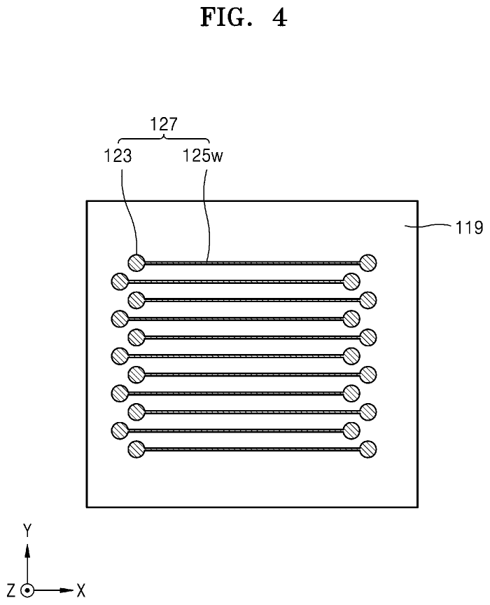

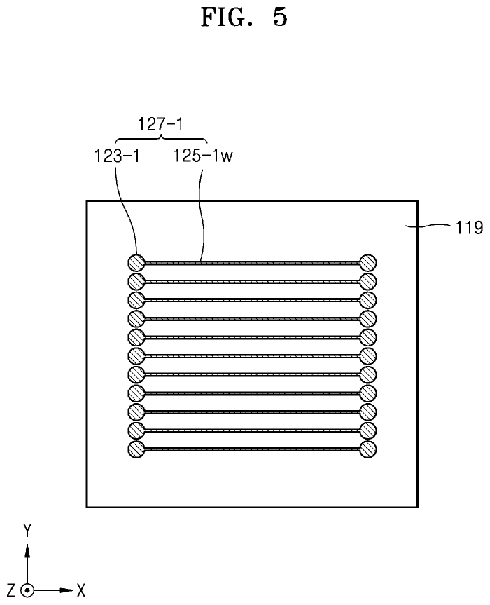

FIGS. 4 and 5 are plan views illustrating bridge wiring structures 127 and 127-1 that may each be positioned on the FICS of FIG. 1 according to some embodiments.

Specifically, as illustrated in FIG. 4, the bridge wiring structure 127 may include a plurality of bridge pads 123 and a bridge wiring layer 125 having a plurality of bridge wiring lines 125w.

The plurality of bridge pads 123 may be spaced apart from one another in a first horizontal direction (e.g., the X direction) and may have at least some of the plurality of bridge pads 123 that are not aligned in the second horizontal direction (e.g., the Y direction). Each of the plurality of bridge wiring lines 125w may be electrically insulated from one another and electrically connect two bridge pads 123 of the plurality of bridge pads 123 which may be spaced apart from each other in the first horizontal direction (e.g., the X direction). The bridge wiring lines 125w may provide an electrical connection between a first chip electrically connected to a first bridge pad 123 and a second chip electrically connected to a second bridge pad 123.

As illustrated in FIG. 5, the bridge wiring structure 127-1 may include a plurality of bridge pads 123-1 and a bridge wiring layer 125 having a plurality of bridge wiring lines 125-1w. The bridge wiring structure 127-1 may correspond to the bridge wiring structure 127 of FIG. 4. The plurality of bridge pads 123-1 may be spaced apart from one another while being aligned in the second horizontal direction (e.g., the Y direction). Each of the plurality of bridge wiring lines 125-1w may be electrically insulated from one another and electrically connect two bridge pads 123-1 that are spaced apart from each other in the first horizontal direction (e.g., the X direction). The bridge wiring lines 125-1w may provide an electrical connection between a first chip electrically connected to a first bridge pad 123-1 and a second chip electrically connected to a second bridge pad 123-1.

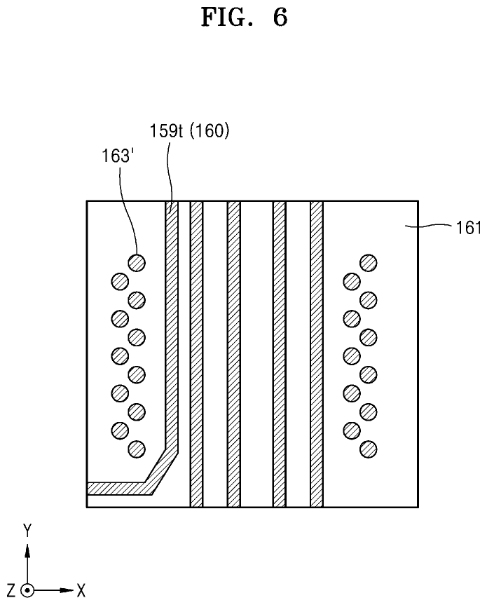

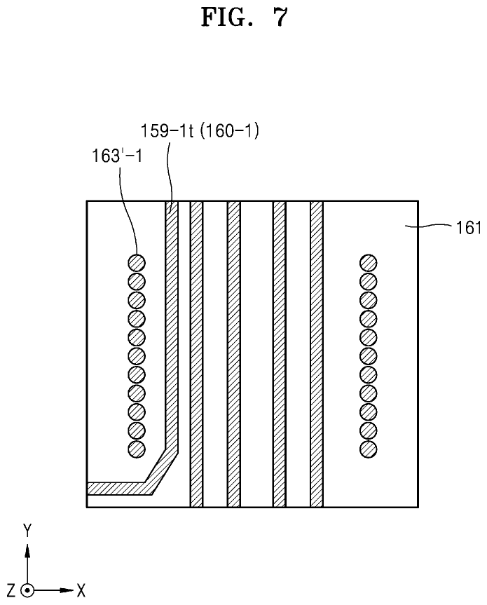

FIGS. 6 and 7 are plan views illustrating second redistribution elements 160 and 160-1 and a plurality of chip connection second redistribution pads 163′ and 163′-1, which are positioned on the FICS of FIG. 1. As shown in FIG. 3, the plurality of chip connection second redistribution pads 163′ and 163-1′ may be connected to second redistribution vias 157 to extend vertically to the first redistribution structure 145.

Specifically, as illustrated in FIG. 6, the second redistribution elements 160 may include a second redistribution layer 159 having a plurality of redistribution conductive traces 159t extending in a first horizontal direction (e.g., the X direction) and/or a second horizontal direction (e.g., the Y direction). As illustrated in FIG. 6, the plurality of chip connection second redistribution pads 163′ may be apart from one another wherein at least some of the second redistribution pads 163′ are not aligned in a second horizontal direction (e.g., the Y direction).

As illustrated in FIG. 7, the second redistribution elements 160-1 may include a second redistribution layer 159-1 having a plurality of redistribution conductive traces 159t extending in a first horizontal direction (e.g., the X direction) and/or a second horizontal direction (e.g., the Y direction). As illustrated in FIG. 7, the plurality of chip connection second redistribution pads 163′-1 may 1 may be spaced apart from one another while being aligned in a second horizontal direction (e.g., the Y direction). The second redistribution elements 160-1 and the plurality of chip connection second redistribution pads 163′-1 may correspond to the second redistribution elements 160 and the plurality of second redistribution pads 163′, respectively.

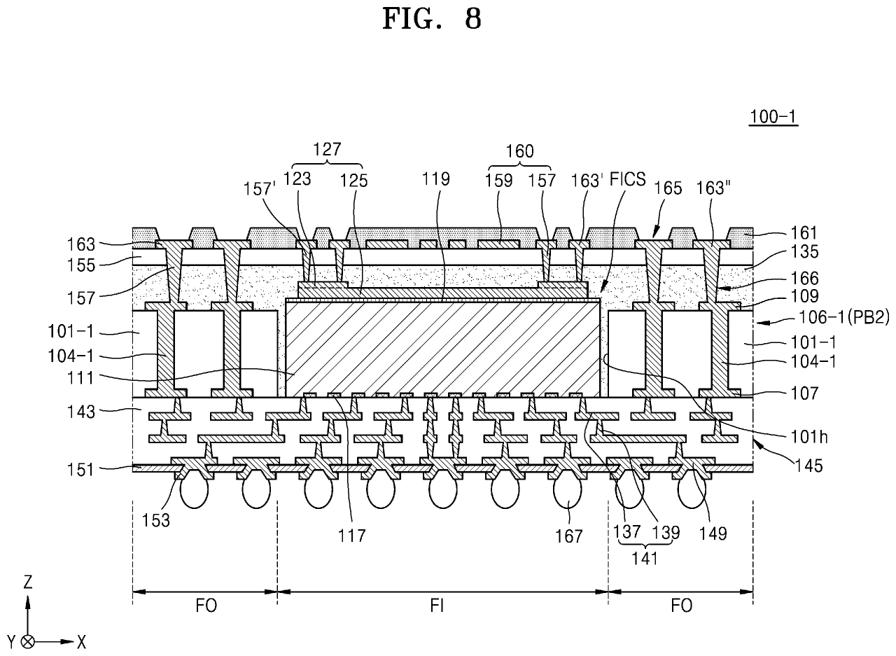

FIG. 8 is a cross-sectional view illustrating a main part of a semiconductor package 100-1 according to an embodiment.

Specifically, the semiconductor package 100-1 may be substantially similar to, or the same as, the semiconductor package 100 of FIGS. 1 to 3, except that the wiring board 106-1 of the example shown in FIG. 8 is different from the wiring board 106 shown in the example of FIGS. 1 to 3. In FIG. 8, the same reference numerals as in FIGS. 1 to 3 denote the same elements and elements having an appended 1 denote different elements that may be similar to, but are not the same as, the elements having the same reference number without the appended 1. In FIG. 8, for elements having a description previously given with reference to FIGS. 1 to 3 further description may be simply given or omitted.

The semiconductor package 100-1 includes a package body PB2. The package body may include the wiring board 106-1. The wiring board 106-1 may be a part of the package body PB2. The package body PB2 may include a package element. The wiring board 106-1 may include a semiconductor substrate. The semiconductor package 100-1 may include a fan out wafer level package (FOWLP). The wiring board 106-1 may include a body 101-1, a body wiring structure 104-1 positioned within the body 101-1, and body wiring pads 107 and 109.

The body 101-1 may be formed of and/or include a semiconductor material, for example, a semiconductor element such as silicon (Si) or germanium (Ge) or a compound semiconductor such as silicon carbide (SiC), gallium arsenide (GaAs), indium arsenide (InAs), or indium phosphide (InP). The body wiring structure 104-1 may include a body wiring layer formed in the body 101-1. The body wiring layer may be formed of and/or include a metal layer, for example, Cu. As described above, in the semiconductor package 100-1, the semiconductor substrate may be used as the wiring board 106-1.

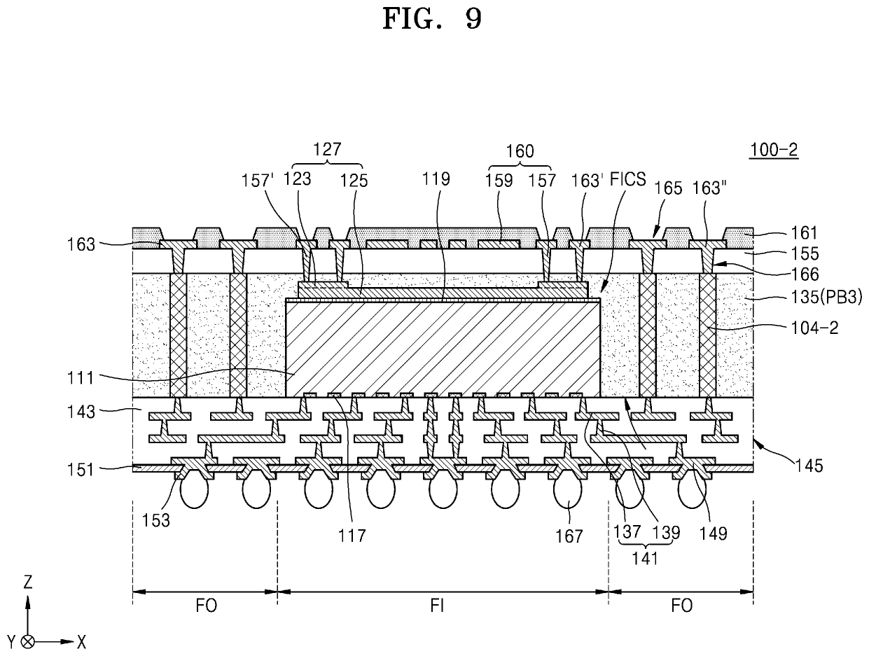

FIG. 9 is a cross-sectional view illustrating a main part of a semiconductor package 100-2 according to an embodiment.

Specifically, the semiconductor package 100-2 may be substantially similar to, or the same as, the semiconductor package 100 of FIGS. 1 to 3, except that a package body PB3 and a body wiring structure 104-2 are different from the package body PB1 and the body wiring structure 104 of FIGS. 1 to 3, respectively. In FIG. 9, the same reference numerals as in FIGS. 1 to 3 denote the same elements and elements having an appended 2 denote different elements that may be similar to, but are not the same as the element having the same reference number without the appended 2. In FIG. 9, for elements having a description previously given with reference to FIGS. 1 to 3 further description may be simply given or omitted.

The semiconductor package 100-2 includes a package body PB3. The package body includes an encapsulation layer 135. The encapsulation layer 135 may be a part of the package body PB3. The package body PB3 may include a package element. The semiconductor package 100-2 may include a fan-out wafer level package (FOWLP).

A body wiring structure 104-2 may be formed in the encapsulation layer 135. The body wiring structure 104-2 may include a metal post, for example, a Cu post. The body wiring structure 104-2 may include a body wiring layer. As described above, in the semiconductor package 100-2, the encapsulation layer 135 may be used as a part of the package body PB3.

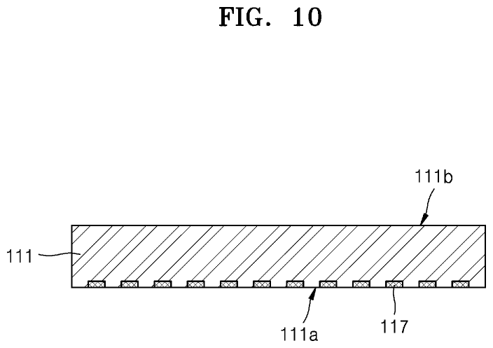

FIGS. 10 to 17 are cross-sectional views illustrating a method of manufacturing the semiconductor package 100 of FIGS. 1 to 3 according to an embodiment.

Specifically, in FIGS. 10 to 17, the same reference numerals as in FIGS. 1 to 3 denote the same members. In FIGS. 10 to 17, for elements having a description previously given with reference to FIGS. 1 to 3 further description may be simply given or omitted.

Referring to FIG. 10, the first chip 111 is prepared (e.g., the first chip 111 is provided, obtained, or formed). The first chip 111 may have the front surface 111a and the rear surface 111b. The front surface 111a may include an active surface on which individual devices are formed, and the rear surface 111b may include an inactive surface on which individual devices are not formed. For convenience, in the first chip 111, the front surface 111a that is the active surface, on which the individual devices are formed, is illustrated as being positioned below rear surface 111b, which is the inactive surface.

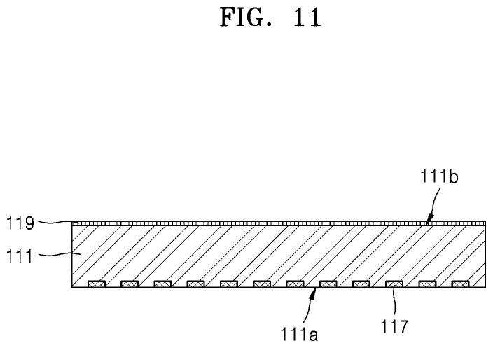

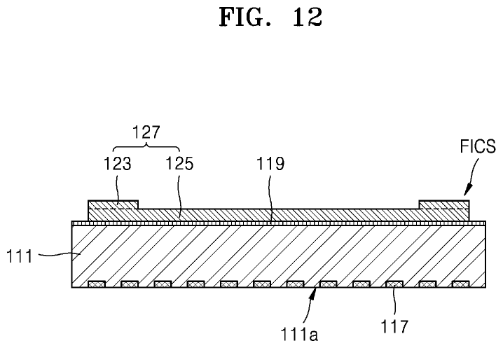

Referring to FIGS. 11 and 12, as illustrated in FIG. 11, the insulating layer 119 is formed on the rear surface 111b of the first chip 111. The insulating layer 119 may include an oxide layer or a nitride layer. The insulating layer 119 may be formed on the rear surface 111b of the first chip 111 through a deposition process. Subsequently, as illustrated in FIG. 12, the bridge wiring structure 127 is formed on the insulating layer 119.

The bridge wiring structure 127 is formed on the first chip 111 by forming the bridge wiring layer 125 and the bridge pads 123 electrically connected to the bridge wiring layer 125 on the rear surface 111b of the first chip 111. Processes including photoresist coating, etching, and deposition may be used to form the bridge wiring structure 127. Through the above process, the FICS including the first chip 111 and the bridge wiring structure 127 may be manufactured.

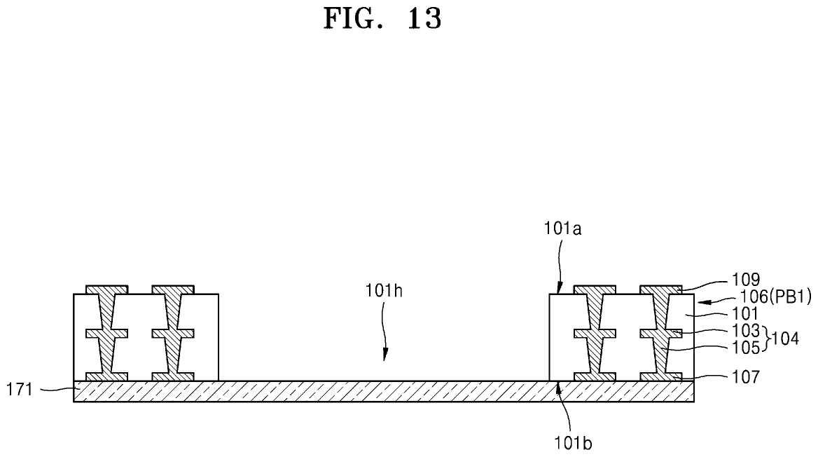

Referring to FIG. 13, the wiring board 106 having the through hole 101h is prepared (e.g., the wiring board 106 is provided, obtained, or formed). The wiring board 106 may constitute the package body PB1. The wiring board 106 may include an insulation board. The wiring board 106 may include the body 101 positioned about the through hole 101h, the body wiring structure 104 formed in the body 101, and the first and second body wiring pads 107 and 109.

The body wiring structure 104 may include the body wiring layer 103 formed in the body 101 and the body vias 105 connecting the body wiring layer 103. The first body wiring pads 107 are positioned on the bottom surface 101b of the body 101 and the second body wiring pads 109 are positioned on the top surface 101a of the body 101. The first body wiring pads 107 may be a part of the body wiring layer 103 positioned on the bottom surface 101b of the body 101. The second body wiring pads 109 may be a part of the body wiring layer 103 positioned on the top surface 101a of the body 101.

Subsequently, the wiring board 106 in which the through hole 101h is formed is attached onto a tape board 171. The wiring board 106 is attached onto the tape board 171 so that the second body wiring pads 109 positioned on the lowermost surface of the wiring board 106 are attached to the tape board 171. The wiring board 106 may be positioned so that the through hole 101h may be positioned over the center of the tape board 171, and the body 101 away from the center of the tape board 171.

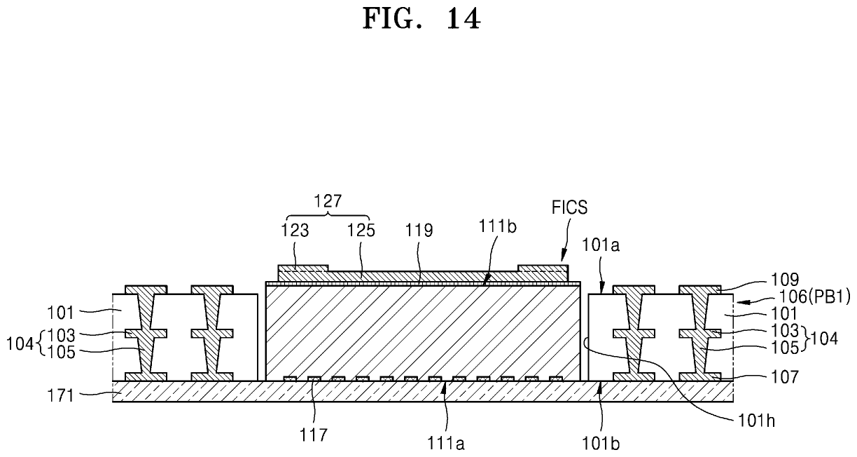

Referring to FIG. 14, the FICS is attached to the tape board 171 with the first chip pads 117 facing the tape board in the through hole 101h of the wiring board 106. The first chip 111 is attached to the tape board 171 with the active surface, that is, the front surface 111a, on which the first chip pads 117 are formed, facing downward towards the tape board 171.

In this case, the FICS including the first chip 111 and the bridge wiring structure 127 may be positioned in the through hole 101h. The rear surface 111b of the first chip 111 may be at a higher level than the top surface 101a of the body 101 constituting the wiring board 106.

When the FICS is attached to the tape board 171, the FICS may be spaced apart from one side of the wiring board 106 such that there is a gap between the wiring board 106 and the body 101. When the FICS is spaced apart from the wiring board 106, a top surface of the tape board 171 may be exposed between the FICS and the wiring board 106.

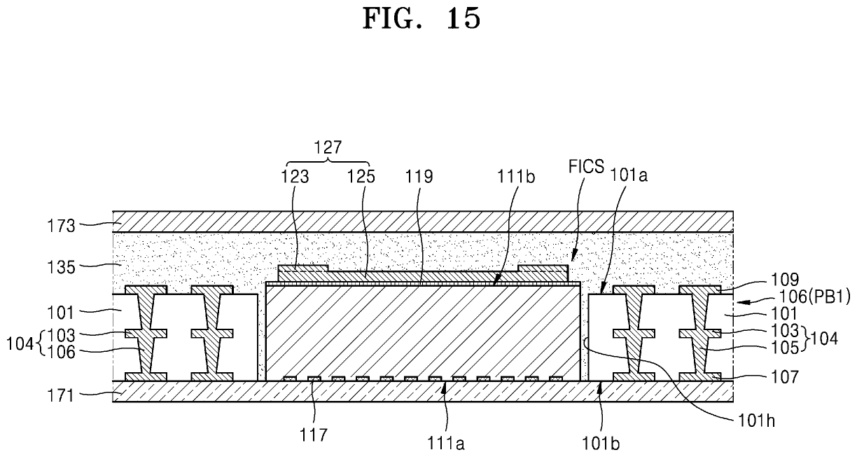

Referring to FIG. 15, the encapsulation layer 135 is formed on the tape board 171 to seal the FICS and the wiring board 106. The encapsulation layer 135 is formed thick enough to sufficiently seal the FICS and the wiring board 106.

The encapsulation layer 135 is formed thicker than the top surface 101a of the body 101 and a top surface of the bridge wiring structure 127. Subsequently, a first carrier substrate 173 is attached onto the encapsulation layer 135. The first carrier substrate 173 may include an insulation board or a semiconductor substrate.

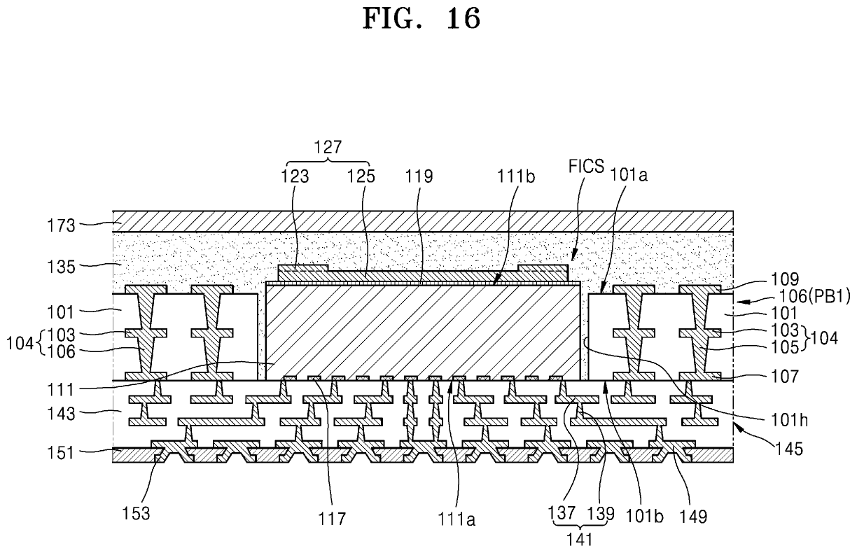

Referring to FIG. 16, the tape board 171 (refer to FIG. 15) is removed. Subsequently, the first redistribution structure 145 is formed on the front surface 111a of the first chip 111 constituting the FICS and the bottom surface 101b of the wiring board 106. The first redistribution structure 145 may be formed using processes including photoresist coating, etching, and deposition. The first redistribution structure 145 may be arranged on the bottom surface 101b of the wiring board 106 and the bottom surface of the FICS.

The first redistribution structure 145 may include the first redistribution insulating layer 143, the first redistribution elements 141, and the first redistribution pads 149. Each of the first redistribution elements 141 may include a first redistribution layer 137 and a first redistribution vias 139 connecting the first redistribution layer 137.

The first redistribution elements 141 may be electrically connected to the first chip pads 117. As described above, the first redistribution structure 145 may extend to the fan-out region FO (refer to FIG. 1) to be electrically connected to the first body wiring pads 107.

The first redistribution pads 149 may be electrically connected to the first redistribution structure 145. The first redistribution pads 149 positioned on the top surface of the first redistribution insulating layer 143 may be parts of the first redistribution layer 137.

Subsequently, the barrier metal layer 153 separated by the first protective layer 151 may be formed on the first redistribution pads 149. The first protective layer 151 includes an insulating layer, for example, an oxide layer or a nitride layer. The barrier metal layer 153 and the first protective layer 151 may be formed using processes including photoresist coating, etching, and deposition.

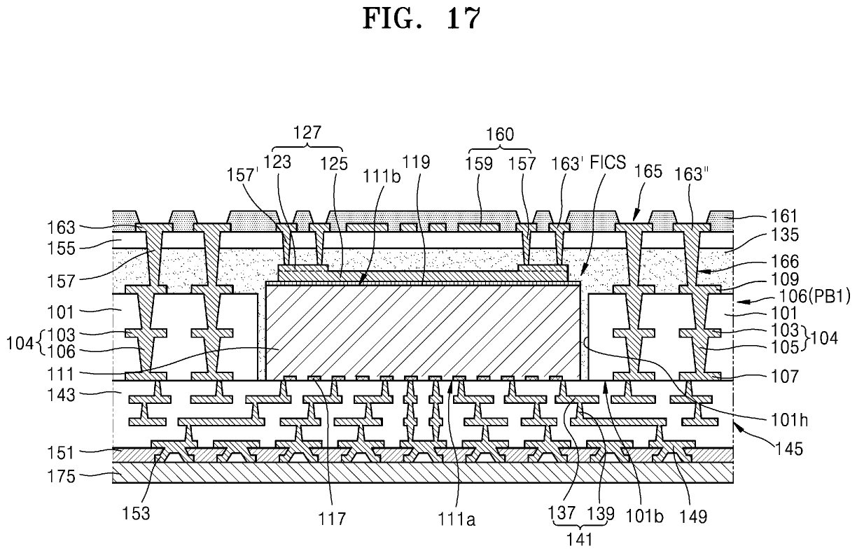

Referring to FIG. 17, the first carrier substrate 173 (refer to FIG. 16) formed on the encapsulation layer 135 is removed. A second carrier substrate 175 is attached onto the barrier metal layer 153 and the first protective layer 151. The second carrier substrate 175 may include an insulation board or a semiconductor substrate.

Subsequently, the second redistribution structure 166 is formed on the top surface 101a of the wiring board 106 and the top surface of the bridge wiring structure 127. The second redistribution structure 166 may include the second redistribution elements 160 formed in the encapsulation layer 135 and insulated by the second redistribution insulating layer 155. The second redistribution structure may be formed using processes including photoresist coating, etching, and deposition.

The second redistribution elements 160 may include the second redistribution layer 159 and the second redistribution vias 157. The second redistribution elements 160 may be electrically connected to the bridge wiring structure 127. The second redistribution vias 157 may include the bridge pad second redistribution vias 157′, which are electrically connected to the bridge pads 123.

The second redistribution layer 159 may extend to the fan-out region FO (refer to FIG. 1) to be redistributed in a plan view. The second redistribution elements 160 may be electrically connected to the bridge pads 123 in the fan-in region FI (refer to FIG. 1). The second redistribution elements 160 may be electrically connected to the second redistribution vias 157 in the fan-out region FO (refer to FIG. 1). The second redistribution structure 166 may include the second redistribution pads 163 electrically connected to the second redistribution elements 160.

As described above, the second redistribution pads 163 may include the chip connection second redistribution pads 163′, which are electrically connected to the second redistribution elements 160 arranged on the top surface of the bridge wiring structure 127. The chip connection second redistribution pads 163′ may be electrically connected to the bridge pad second redistribution vias 157′. As described above, the second redistribution pads 163 may include the body connection second redistribution pads 163″, which are electrically connected to the second redistribution elements 160 arranged on the top surface of the package body PB1.

The second redistribution pads 163 may be a part of the second redistribution layer 159. The second redistribution pads 163 may be electrically separated by the second protective layer 161. The second redistribution pads 163 may be exposed to the outside by the pad exposure holes 165.

Subsequently, the second carrier substrate 175 is removed. When the first external connection terminals 167 (refer to FIG. 1), for example, the solder balls are formed on the barrier metal layer 153, the semiconductor package 100 illustrated in FIGS. 1 to 3 may be manufactured.

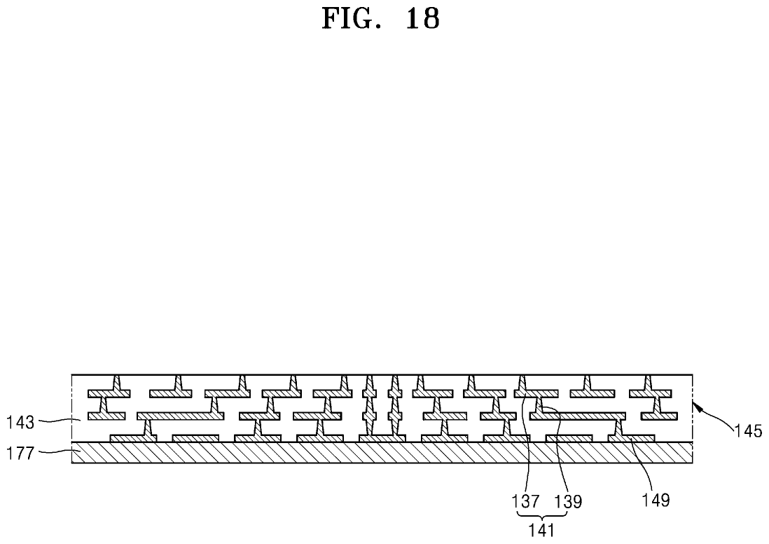

FIGS. 18 to 21 are cross-sectional views illustrating a method of manufacturing the semiconductor package of FIG. 9 according to an embodiment.

Specifically, FIGS. 18 to 21 may be substantially the same as FIGS. 10 to 17 except for a difference in formation order of the first redistribution structure 145, the FICS, and the second redistribution structure 166.

FIGS. 18 to 21 illustrate that the first redistribution structure 145 is formed on the bottom surface 101b of the package body PB3 (refer to FIG. 9), the FICS is formed in the package body PB3 (refer to FIG. 9), and the second redistribution structure 166 is formed on the FICS. In FIGS. 18 to 21, the same reference numerals as in FIGS. 1 to 3 and 10 to 17 denote the same members. In FIGS. 18 to 21, description previously given with reference to FIGS. 1 to 3 and 10 to 17 is simply given or omitted.

Referring to FIG. 18, the first redistribution structure 145 is formed on a carrier substrate 177. The carrier substrate 177 may include an insulation board or a semiconductor substrate. As described above, the first redistribution structure 145 may include the first redistribution insulating layer 143, the first redistribution elements 141, and the first redistribution pads 149. Each of the first redistribution elements 141 may include the first redistribution layer 137 and the first redistribution vias 139 connecting the first redistribution layer 137.

The first redistribution pads 149 may be electrically connected to the first redistribution structure 145. The first redistribution pads 149 positioned on the top surface of the first redistribution insulating layer 143 may be parts of the first redistribution layer 137.

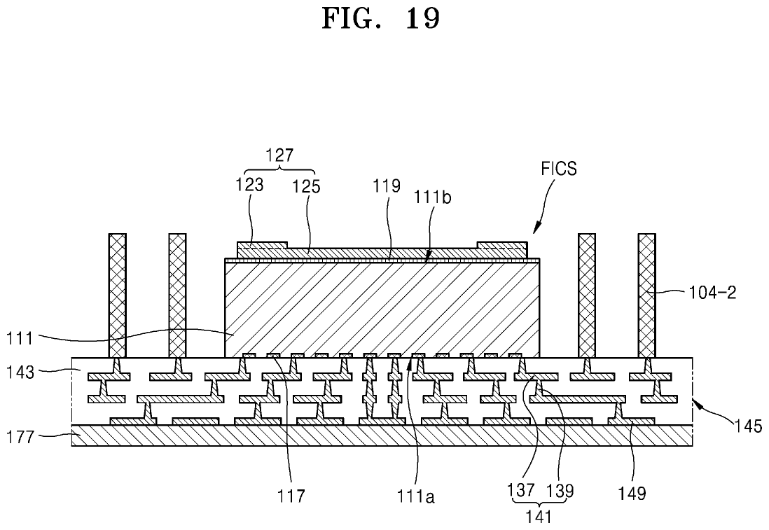

Referring to FIG. 19, the body wiring structure 104-2 is formed on the first redistribution structure 145. The body wiring structure 104-2 may be formed in the fan-out region FO (refer to FIG. 9) as illustrated above. The body wiring structure 104-2 may include a metal post, for example, a Cu post.

Subsequently, the FICS including the bridge wiring structure 127 described above with reference to FIGS. 10 to 12 is prepared. Subsequently, the FICS including the bridge wiring structure 127 is mounted on the first redistribution structure 145 by placing the first chip pads 117 downward. In the FICS, the first chip 111 is mounted on the fan-in region FI (refer to FIG. 9) by placing the active surface of the first chip 111, that is, the front surface 111a, on which the first chip pads 117 are formed, downward. A thickness of the body wiring structure 104-2 may be greater than a height (or a thickness) of the FICS or the first chip 111.

In this case, the FICS including the first chip 111 and the bridge wiring structure 127 positioned on the first chip 111, may be positioned in the fan-in region FI. The first chip pads 117 may be electrically connected to the first redistribution elements 141, for example, the first redistribution vias 139.

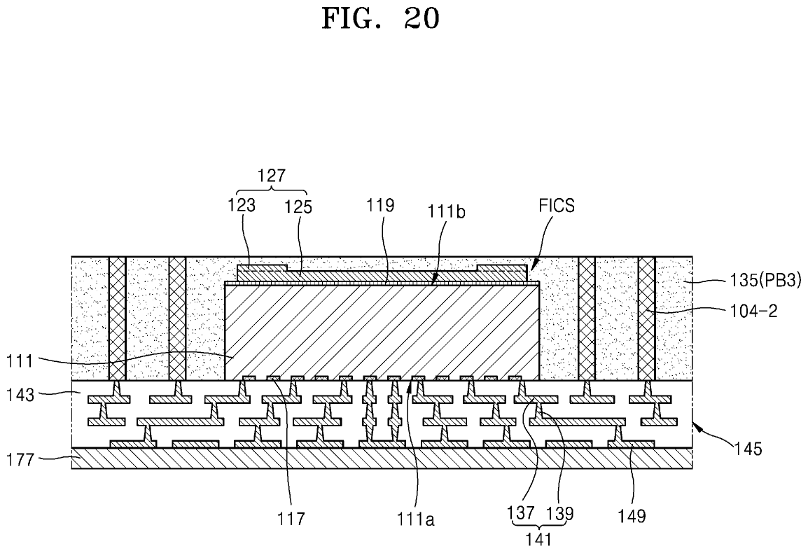

Referring to FIG. 20, the encapsulation layer 135 is formed to a sufficient thickness to seal the FICS and the body wiring structure 104-2 on the first redistribution structure 145. The encapsulation layer 135 may constitute the package body PB3. If necessary, the encapsulation layer 135 may have the same plane as the body wiring structure 104-2 by using a planarization process.

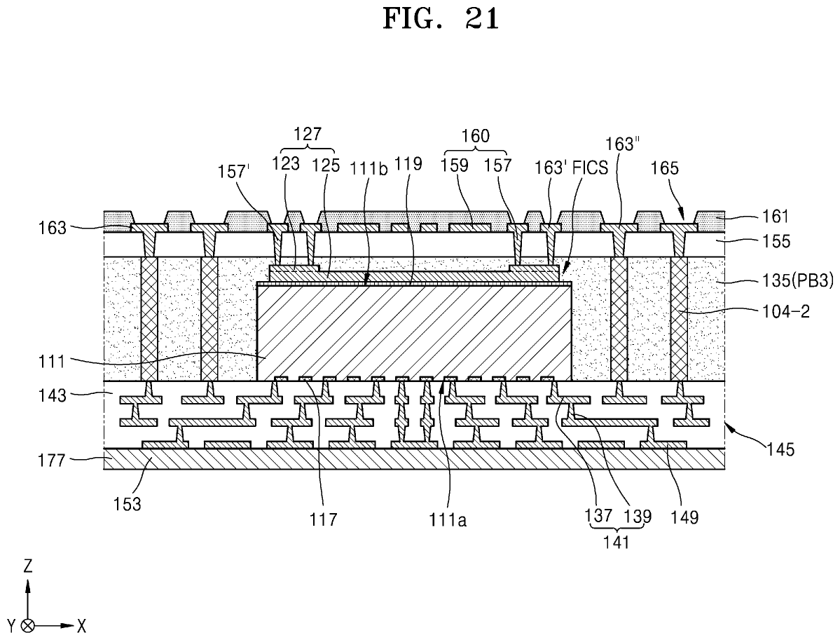

Referring to FIG. 21, the second redistribution structure 166 is formed on the encapsulation layer 135, the FICS, and the body wiring structure 104-2. The second redistribution structure 166 may include the second redistribution elements 160 formed in the encapsulation layer 135 and insulated by the second redistribution insulating layer 155.

The second redistribution elements 160 may include the second redistribution layer 159 and the second redistribution vias 157. The second redistribution elements 160 may be electrically connected to the bridge wiring structure 127 of the FICS. The second redistribution vias 157 may include the bridge pad second redistribution vias 157′, which are electrically connected to the bridge pads 123.

The second redistribution layer 159 may extend to the fan-out region FO (refer to FIG. 9) to be redistributed in a plan view. The second redistribution elements 160 may be electrically connected to the bridge pads 123 in the fan-in region FI (refer to FIG. 9). The second redistribution elements 160 may be electrically connected to the second redistribution vias 157 in the fan-out region FO (refer to FIG. 9). The second redistribution structure 166 may include the second redistribution pads 163 electrically connected to the second redistribution elements 160.

The second redistribution pads 163 may include the chip connection second redistribution pads 163′, which are electrically connected to the second redistribution elements 160 arranged on the top surface of the bridge wiring structure 127. The chip connection second redistribution pads 163′ may be electrically connected to the bridge pad second redistribution vias 157′. The second redistribution pads 163 may include body connection second redistribution pads 163″, which are electrically connected to the second redistribution elements 160 arranged on a top surface of the package body PB3.

The second redistribution pads 163 may be a part of the second redistribution layer 159. The second redistribution pads 163 may be electrically separated from one another or other components by the second protective layer 161. The second redistribution pads 163 may be exposed to the outside of the second redistribution structure 166 by the pad exposure holes 165.

Subsequently, after removing the carrier substrate 177, the barrier metal layer 153 separated by the first protective layer 151 are formed on the first redistribution pads 149 as illustrated in FIG. 9. When the first external connection terminals 167, for example, the solder balls are formed on the barrier metal layer 153, the semiconductor package 100-2 may be manufactured.

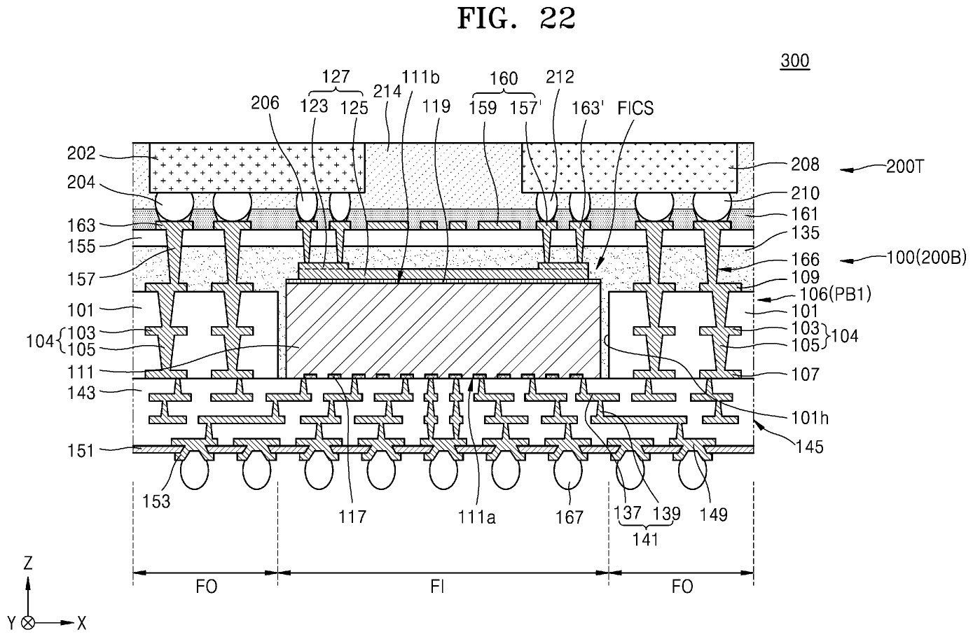

FIG. 22 is a cross-sectional view illustrating a main part of a semiconductor package 300 according to an embodiment.

Specifically, the semiconductor package 300 may include a stacked package in the form of a package-on-package in which an upper package 200T is further stacked on the semiconductor package 100 of FIGS. 1 to 3. In FIG. 22, description previously given with reference to FIGS. 1 to 3 is simply given or omitted. Here, the semiconductor package 100 of FIGS. 1 to 3 is referred to as a lower package 200B.

The semiconductor package 300 may include a stacked package including the lower package 200B and the upper package 200T. The upper package 200T may include a second chip 202 and a third chip 208. The second chip 202 and the third chip 208 may include a logic chip, a power management integrated circuit (PMIC) chip, or a memory chip.

The second chip 202 may be mounted on one side (e.g., a lateral side in a horizontal plane) of the second redistribution structure 166 constituting the lower package 200B. The second chip 202 may be electrically connected to the second redistribution structure 166. A second external connection terminal 204, for example, a second solder ball, may be formed on a part of the second redistribution pads 163. The second external connection terminals 204 may electrically connect the second chip 202 to the second redistribution pads 163.

A third chip 208 may be mounted on the other side of the second redistribution structure 166 constituting the lower package 200B. The third chip 208 may be electrically connected to the second redistribution structure 166. A third external connection terminal 210, for example, a third solder ball, may be formed on a part of the second redistribution pads 163. The third external connection terminal 210 may electrically connect the third chip 208 to the second redistribution pads 163.

The second chip 202 and the third chip 208 may be electrically connected through the bridge pad second redistribution vias 157′ and the bridge wiring structure 127. The bridge wiring structure 127 may serve as an interposer board. Accordingly, the semiconductor package 300 according to the inventive concept may efficiently and densely integrate the additional chips, that is, the second and third chips 202 and 208 stacked on the package body PB1.

The upper package 200T may include an upper encapsulation layer 214 surrounding the second and third chips 202 and 208. The upper encapsulation layer 214 may include, for example, an EMC. In some embodiments, the upper encapsulation layer 214 may expose inactive surfaces of the second and third chips 202 and 208.

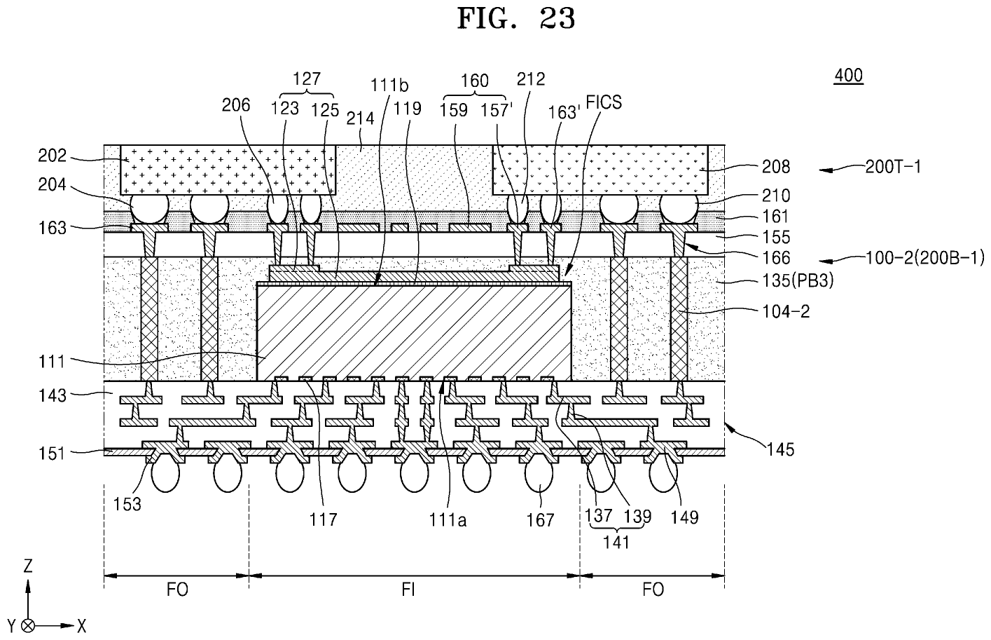

FIG. 23 is a cross-sectional view illustrating a main part of a semiconductor package 400 according to an embodiment.

Specifically, the semiconductor package 400 may include a stacked package in the form of a package-on-package in which an upper package 200T-1 is further stacked on the semiconductor package 100-2 of FIG. 9. In FIG. 23, description previously given with reference to FIG. 9 is simply given or omitted. Here, the semiconductor package 100-2 of FIG. 9 is referred to as a lower package 200B-1.

The semiconductor package 400 may include a stacked package including the lower package 200B-1 and the upper package 200T-1. The upper package 200T-1 may include a second chip 202 and a third chip 208. Each of the second chip 202 and the third chip 208 may include a logic chip, a PMIC chip, or a memory chip.

The second chip 202 may be mounted on one side of the second redistribution structure 166 constituting the lower package 200B-1. The second chip 202 may be electrically connected to the second redistribution structure 166. A second external connection terminal 204, for example, a second solder ball, may be formed on a part of the second redistribution pads 163. The second external connection terminal 204 may electrically connect the second chip 202 to the second redistribution pads 163.

A third chip 208 may be mounted on the other side of the second redistribution structure 166 constituting the lower package 200B. The third chip 208 may be electrically connected to the second redistribution structure 166. A third external connection terminal 210, for example, a third solder ball, may be formed on a part of the second redistribution pads 163. The third external connection terminal 210 may electrically connect the third chip 208 to the second redistribution pads 163.

The second chip 202 and the third chip 208 may be electrically connected through the bridge pad second redistribution vias 157′ and the bridge wiring structure 127. The bridge wiring structure 127 may serve as an interposer board. Accordingly, the semiconductor package 400 according to the inventive concept may efficiently and densely integrate the additional chips, that is, the second and third chips 202 and 208 stacked on the package body PB3.

The upper package 200T-1 may include an upper encapsulation layer 214 surrounding the second and third chips 202 and 208. The upper encapsulation layer 214 may include, for example, an EMC. In some embodiments, the upper encapsulation layer 214 may expose inactive surfaces of the second and third chips 202 and 208.

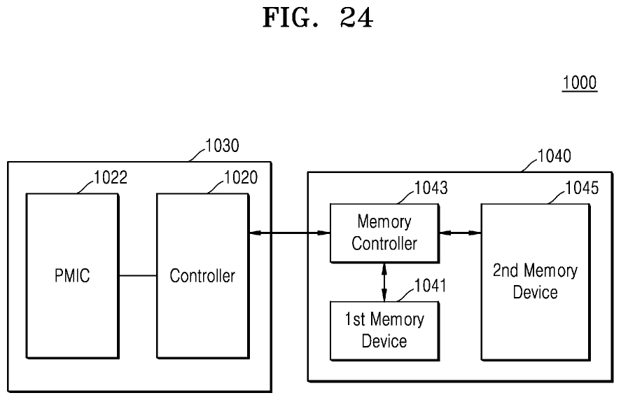

FIG. 24 is a block diagram illustrating a configuration of a semiconductor package 1000 according to an embodiment.

Specifically, the semiconductor package 1000 may correspond to the semiconductor package 100, 100-1, or 100-2 according to the inventive concept. The semiconductor package 1000 may include a controller chip 1020, a first memory chip 1041, a second memory chip 1045, and a memory controller 1043. The semiconductor package 1000 may further include a PMIC chip 1022 supplying a current of an operating voltage to each of the controller chip 1020, the first memory chip 1041, the second memory chip 1045, and the memory controller 1043. Each operating voltage applied to each component may be designed identically or differently.

A lower package 1030 including the controller chip 1020 and the PMIC chip 1022 may 1022 may include the above-described lower package 200B or 200B-1 (refer to FIG. 22 or 23) according to the inventive concept. An upper package 1040 including the first memory chip 1041, the second memory chip 1045, and the memory controller 1043 may include the above-described upper package 200T or 200T-1 (refer to FIG. 22 or 23) according to the inventive concept.

The semiconductor package 1000 may be included in a personal computer (PC) or a mobile device. The mobile device may include a laptop computer, a mobile phone, a smartphone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile Internet device (MID), a wearable computer, an Internet of things (IoT) device, an Internet of everything (IoE) device, or a drone.

The controller chip 1020 may control operations of the first memory chip 1041, the second memory chip 1045, and the memory controller 1043. For example, the controller chip 1020 may 1020 may include an integrated circuit (IC), a system on chip (SoC), an AP, a mobile AP, a chipset, or a set of chips. The controller chip 1020 may include a CPU, a GPU, and/or a modem. In some embodiments, the controller chip 1020 may perform a function of the modem and a function of the AP.

The memory controller 1043 may control the second memory chip 1045 under control of the controller chip 1020. The first memory chip 1041 may include a volatile memory device. The volatile memory device may include random access memory (RAM), dynamic RAM (DRAM), or static RAM (SRAM). However, the inventive concept is not limited thereto. The second memory chip 1045 may include a storage memory device. The storage memory device may include a non-volatile memory device.

The storage memory device may include a flash-based memory device. However, the inventive concept is not limited thereto. The second memory chip 1045 may include a NAND-type flash memory device. The NAND-type flash memory device may include a two-dimensional (2D) memory cell array or a three-dimensional (3D) memory cell array. The 2D memory cell array or the 3D memory cell array may include a plurality of memory cells, and each of the plurality of memory cells may store 1-bit information or 2-bit or more information.

When the second memory chip 1045 includes the flash-based memory device, the memory controller 1043 may use (or support) a multimedia card (MMC) interface, an embedded MMC (eMMC) interface, or a universal flash storage (UFS) interface. However, the inventive concept is not limited thereto.

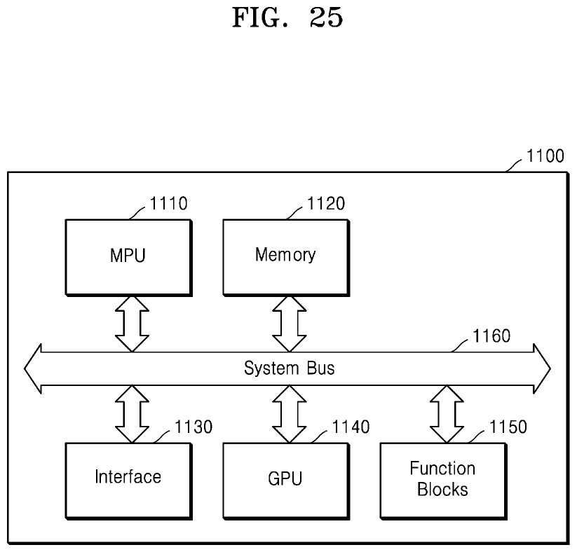

FIG. 25 is a block diagram schematically illustrating a configuration of a semiconductor package 1100 according to an embodiment.

Specifically, the semiconductor package 1100 may include a micro-processing unit (MPU) 1110, a memory 1120, an interface 1130, a GPU 1140, function blocks 1150, and a bus 1160 connecting them. The semiconductor package 1100 may include both the MPU 1110 and the GPU 1140, but may include only one of them.

The MPU 1110 may include a core and an L2 cache. For example, the MPU 1110 may 1110 may include a multi-core. Each core of the multi-core may have the same or different performance. In addition, each core of the multi-core may be activated at the same time or at different times. The memory 1120 may store a result processed by the function blocks 1150 under control of the MPU 1110. For example, as a content stored in the L2 cache of the MPU 1110 is flushed, the content may be stored in the memory 1120. The interface 1130 may interface with external devices. For example, the interface 1130 may interface with a camera, a liquid crystal display (LCD), and a speaker.

The GPU 1140 may perform graphics functions. For example, the GPU 1140 may perform a video codec or may process 3D graphics. The function blocks 1150 may perform various functions. For example, when the semiconductor package 1100 includes an AP used in the mobile device, some of the function blocks 1150 may perform a communication function.

The semiconductor package 1100 may include the semiconductor packages 300 or 400 illustrated in the inventive concept. The MPU 1110 and/or the GPU 1140 may include the lower package 200B or 200B-1 described above. The memory 1120 may include the upper package 200T or 200T-1 described above. The interface 1130 and the function blocks 1150 may correspond to a part of the lower package 200B or 200B-1 described above.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package body;
a fan-in-chip structure (FICS) in the package body, wherein the FICS includes a first chip having a front surface and a rear surface, and a bridge wiring structure including a bridge wiring layer on the rear surface of the first chip and a bridge pad electrically connected to the bridge wiring layer;
a first redistribution structure on a bottom surface of the package body and the front surface of the first chip and including a first redistribution element; and
a second redistribution structure on a top surface of the package body and the rear surface of the first chip and including a second redistribution element electrically connected to the bridge wiring structure.

2. The semiconductor package of claim 1, wherein the first chip comprises a first chip pad on the front surface of the first chip, and
wherein the first redistribution element in the first redistribution structure is electrically connected to the first chip pad.

3. The semiconductor package of claim 1, wherein the first redistribution element comprises a first redistribution layer and a first redistribution via, and
wherein the second redistribution element comprises a second redistribution layer and a second redistribution via.

4. The semiconductor package of claim 1, wherein the second redistribution structure further comprises a body connection second redistribution pad, and
wherein the body connection second redistribution pad is electrically connected to the second redistribution element on the top surface of the package body.

5. The semiconductor package of claim 1, wherein the second redistribution structure further comprises a chip connection second redistribution pad, and
wherein the chip connection second redistribution pad is electrically connected to the second redistribution element on a top surface of the bridge wiring structure.

6. The semiconductor package of claim 1, wherein the package body comprises a wiring board having a through hole in an internal region of the wiring board, and
wherein the FICS is embedded in the through hole and is sealed by an encapsulation layer.

7. The semiconductor package of claim 1, wherein the package body comprises a semiconductor substrate having a through hole in an internal region of the semiconductor substrate, and a body wiring structure passing through top and bottom surfaces of the semiconductor substrate, and
wherein the body wiring structure is electrically connected to the first redistribution element and the second redistribution element.

8. The semiconductor package of claim 1, wherein the package body comprises an encapsulation layer sealing the FICS and a body wiring structure passing through top and bottom surfaces of the encapsulation layer, and
wherein the body wiring structure is electrically connected to the first redistribution element and the second redistribution element.

9. A semiconductor package comprising:
a package body having a fan-in region and a fan-out region surrounding the fan-in region, wherein the package body comprises a wiring board having a through hole in an internal region of the wiring board or a semiconductor substrate having a through hole in an internal region of the semiconductor substrate, and a body wiring structure is formed in the package body of the fan-out region;
a fan-in-chip structure (FICS) in the fan-in region, wherein the FICS includes a first chip having a front surface that is an active surface and a rear surface that is an inactive surface, and a bridge wiring structure including a bridge wiring layer on the rear surface of the first chip and a bridge pad electrically connected to the bridge wiring layer;
a first redistribution structure on a bottom surface of the package body and the front surface of the first chip and including a first redistribution element extending from the fan-in region to the fan-out region; and
a second redistribution structure on a top surface of the package body and the rear surface of the FICS and including a second redistribution element extending from the fan-in region to the fan-out region and electrically connected to the bridge wiring structure.

10. The semiconductor package of claim 9, wherein the bridge wiring structure is arranged in the fan-in region and does not extend into the fan-out region, wherein the bridge wiring structure is electrically connected to the second redistribution element in the fan-in region, wherein a first chip pad is arranged on the front surface of the first chip, and
wherein the first redistribution element is electrically connected to the first chip pad in the fan-in region.

11. The semiconductor package of claim 9, wherein the package body comprises the wiring board and the FICS is embedded in the through hole and is sealed by an encapsulation layer.

12. The semiconductor package of claim 9, wherein the second redistribution structure further comprises another second redistribution element on the top surface of the package body and a body connection second redistribution pad, electrically connected to the other second redistribution element, and a chip connection second redistribution pad electrically connected to the second redistribution element on a top surface of the bridge wiring structure.

13. The semiconductor package of claim 9, wherein the second redistribution element further comprises a chip connection second redistribution pad, electrically connected to the bridge pad in the fan-in region.

14. The semiconductor package of claim 9, wherein the package body comprises the semiconductor substrate, the body wiring structure, a first body wiring pad electrically connected to the body wiring structure and positioned at a bottom surface of the package body, and a second body wiring pad electrically connected to the body wiring structure and positioned at the top surface of the package body, wherein the first redistribution structure is electrically connected to the first body wiring pad in the fan-out region, and
wherein the second redistribution structure is electrically connected to the second body wiring pad in the fan-out region.

15. The semiconductor package of claim 9, wherein the first chip comprises a first chip pad on the front surface of the first chip, and the first redistribution element in the first redistribution structure is electrically connected to the first chip pad.

16. A semiconductor package comprising:
a lower package; and
an upper package stacked on the lower package, wherein the lower package comprises:
a package body having a body wiring structure, a fan-in region, and a fan-out region surrounding the fan-in region, wherein the body wiring structure is formed in the package body of the fan-out region;
a fan-in-chip structure (FICS) in the fan-in region, wherein the FICS includes a first chip having a front surface that is an active surface and a rear surface that is an inactive surface, and a bridge wiring structure including a bridge wiring layer on the rear surface of the first chip and a bridge pad electrically connected to the bridge wiring layer;
a first redistribution structure on a bottom surface of the package body and the front surface of the first chip and including a first redistribution element extending to the fan-out region; and
a second redistribution structure on a top surface of the package body and a top surface of the bridge wiring structure and including a second redistribution element extending to the fan-out region and electrically connected to the bridge wiring structure, and
wherein the upper package comprises:
a second chip mounted on a first side of the second redistribution structure and electrically connected to the second redistribution structure, and
a third chip mounted on a second side of the second redistribution structure and electrically connected to the second redistribution structure.

17. The semiconductor package of claim 16, wherein the first redistribution structure further comprises a first redistribution pad electrically connected to the first redistribution element, and
wherein a first external connection terminal is further formed on the first redistribution pad.

18. The semiconductor package of claim 16, wherein the second redistribution structure further comprises a second redistribution pad electrically connected to the second redistribution element, and another second redistribution pad electrically connected to the second redistribution element, and
wherein a second external connection terminal electrically connected to the second chip is formed on the second redistribution pad and a third external connection terminal electrically connected to the third chip is formed on the other second redistribution pad.

19. The semiconductor package of claim 18, further comprising a body connection second redistribution pad,
wherein the second redistribution pad is a chip connection second redistribution pad,
wherein the body connection second redistribution pad is electrically connected to a body wiring pad, and
wherein the chip connection second redistribution pad is electrically connected to the bridge pad.

20. The semiconductor package of claim 18, wherein the package body comprises one of a wiring board having a through hole in the fan-in region, a semiconductor substrate having a through hole in the fan-in region, or an encapsulation layer sealing the FICS in the fan-in region and formed in the fan-out region.
